(19) United States
(12) Patent Application Publication
(10) Pub. No.: US 2026/0058644 A1
(43) Pub. Date: Feb. 26, 2026

(54) Clock Generation Circuit With Time Delay Adjustment

(71) Applicant: Mixed-Signal Devices Inc., Irvine, CA (US)

(72) Inventor: Tommy Yu, Orange, CA (US)

(73) Assignee: Mixed-Signal Devices Inc., Irvine, CA (US)

(21) Appl. No.: 19/305,659

(22) Filed: Aug. 20, 2025

Related U.S. Application Data
(60) Provisional application No. 63/685,220, filed on Aug. 20, 2024.

(51) Int. Cl. H03K 5/131; H03K 5/00; H03K 23/68

(52) U.S. Cl. CPC H03K 5/131; H03K 23/68; H03K 2005/00058

(57) ABSTRACT

In many embodiments of the invention, a clock generation circuit includes a numerically controlled oscillator to receive a frequency control word and generate a fractional time signal, a variable delay circuit including a buffer driving a variable switch-capacitor network, the variable delay circuit configured to receive the fractional time signal and generate a delayed clock signal with a time delay that is linear with total capacitance at a load using probabilistic delay assignment, and a probabilistic delay assignment circuit to select between a first delay setting including delay line only and a second delay setting including a sample clock period delay plus delay line, wherein the probabilistic delay assignment circuit assigns probabilities p1=m1/L and p2=(L−m1)/L for selecting the first and second delay settings, where m1 represents a fractional portion of a desired delay and L represents a ratio between sample clock period and unit delay.

### CROSS-REFERENCE TO RELATED APPLICATIONS

This application claims priority to U.S. Application No. 63/685,220, titled Clock Generation Circuit with Time Delay Adjustment, filed Aug. 20, 2024, which is hereby incorporated by reference in its entirety.

### FIELD OF INVENTION

The present invention relates to clock generation circuits, and more particularly to a clock generation circuit with time delay adjustment that uses probabilistic delay assignment and ratio estimation to minimize spurious signals and improve timing accuracy.

### BACKGROUND

Clock generation with delay adjustment has been widely used in digital clock synthesis, especially in fractional clock divider circuit design.

Clock generation forms the foundation of modern digital systems, providing the timing references that synchronize operations across processors, memory controllers, communication interfaces, and other digital components. The precision and stability of these clock signals impact system performance, power consumption, and overall functionality. As digital systems have evolved to support higher data rates and more complex operations, the demands on clock generation circuits have increased correspondingly.

Fractional clock dividers represent a particularly valuable class of clock generation circuits that enable the synthesis of output frequencies that are non-integer multiples of input reference frequencies. These circuits find widespread application in phase-locked loops, frequency synthesizers, digital signal processing systems, and communication transceivers where precise frequency control is needed. The ability to generate fractional frequency relationships allows system designers to optimize performance while maintaining compatibility with various interface standards and protocols.

Traditional clock generation approaches face several challenges when implementing delay adjustment capabilities. Achieving precise timing control while maintaining low jitter performance presents design trade-offs between complexity and accuracy. Process variations, temperature fluctuations, and supply voltage changes can introduce timing errors that degrade system performance. Additionally, conventional delay adjustment techniques may suffer from non-linearities that result in spurious frequency components in the output spectrum, which can interfere with system operation.

### SUMMARY

In many embodiments of the invention, a clock generation circuit includes a numerically controlled oscillator (NCO) configured to receive a frequency control word and generate a fractional time signal, a variable delay circuit comprising a buffer driving a variable switch-capacitor network, the variable delay circuit configured to receive the fractional time signal and generate a delayed clock signal with a time delay that is linear with total capacitance at a load using probabilistic delay assignment, and a probabilistic delay assignment circuit configured to select between a first delay setting comprising delay line only and a second delay setting comprising a sample clock period delay plus delay line, wherein the probabilistic delay assignment circuit assigns probabilities p1=m1/L and p2=(L−m1)/L for selecting the first and second delay settings respectively, where m1 represents a fractional portion of a desired delay and L represents a ratio between a sample clock period and a unit delay.

In several embodiments of the invention, the numerically controlled oscillator comprises an adder/subtractor configured to process the frequency control word and a multiplexer configured to receive feedback signals.

In some embodiments of the invention, the variable switch-capacitor network comprises a plurality of switching elements that are selectively activated to achieve different capacitive loads and corresponding delay values.

In further embodiments of the invention, the variable delay circuit incorporates a zero-DNL DAC configuration for linear skew control to minimize jitter in the delayed clock signal.

More embodiments of the invention also include a ratio estimation circuit configured to continuously monitor a relationship between a sample clock period Ts and a unit delay td of the variable delay circuit.

In still further embodiments of the invention, the ratio estimation circuit compares the first delay setting and the second delay setting for delays between Ts and 2Ts to detect scaling errors.

In still more embodiments of the invention, the probabilistic delay assignment circuit converts delay errors to zero-mean additive white noise using stochastic signal processing to eliminate periodic spurious signals.

In many embodiments of the invention, a method for generating a clock signal with delay adjustment includes receiving a frequency control word at a numerically controlled oscillator, generating a fractional time signal based on the frequency control word, applying the fractional time signal to a variable delay circuit comprising a buffer driving a variable switch-capacitor network to produce a time delay that is linear with total capacitance at a load using probabilistic delay assignment, and probabilistically selecting between a first delay implementation using delay line only and a second delay implementation using a sample clock period delay plus delay line, wherein the probabilistic selection uses probabilities p1=m1/L and p2=(L−m1)/L, where m1 represents a fractional portion of a desired delay and L represents a ratio between a sample clock period and a unit delay.

In several embodiments of the invention, generating the fractional time signal comprises processing the frequency control word through an adder/subtractor and maintaining an accumulator register that tracks fractional timing relationships.

In some embodiments of the invention, the accumulator register increments by a ratio N/M when an output clock signal equals 1 and decrements by 1 at every sample clock cycle otherwise, where N/M represents the frequency control word.

In further embodiments of the invention, the variable switch-capacitor network comprises a plurality of switching elements that are selectively activated to achieve different capacitive loads corresponding to different delay values.

In many embodiments of the invention, applying the fractional time signal comprises utilizing a zero-DNL DAC configuration for linear skew control to minimize jitter in a resulting delayed clock signal.

More embodiments of the invention also include continuously monitoring a relationship between a sample clock period Ts and a unit delay td using a ratio estimation circuit operating in background.

In still further embodiments of the invention, the ratio estimation circuit compares actual delays produced by the first delay implementation and the second delay implementation to detect scaling errors and update the ratio L accordingly.

In still more embodiments of the invention, a fractional clock divider circuit includes an accumulator configured to maintain a count value based on a frequency control word, a comparator configured to generate an output clock signal when the count value drops below a threshold, a delay adjustment circuit comprising a switch-capacitor network configured to provide variable time delays that are linear with capacitance, and a ratio estimation circuit configured to estimate a ratio between a sample clock period and a unit delay by comparing two delay implementations for delays between the sample clock period and twice the sample clock period, wherein a first delay implementation uses delay line only and a second delay implementation uses the sample clock period delay plus delay line.

In many embodiments of the invention, the accumulator is configured to increment by a ratio N/M when the output clock signal equals 1 and decrement by 1 at every sample clock cycle otherwise, where N/M represents the frequency control word.

In several embodiments of the invention, the switch-capacitor network comprises a plurality of switching elements that are selectively activated to achieve different capacitive loads corresponding to different delay values.

In some embodiments of the invention, the delay adjustment circuit incorporates a zero-DNL DAC configuration for linear skew control to minimize jitter in a delayed output signal.

In further embodiments of the invention, the ratio estimation circuit operates continuously in background and updates the ratio estimation when a difference is detected between actual delays produced by the first delay implementation and the second delay implementation.

In more embodiments of the invention, the ratio estimation circuit generates a pulse width signal having a DC value of zero when the ratio estimation is accurate.

### BRIEF DESCRIPTION OF FIGURES

Non-limiting and non-exhaustive examples are described with reference to the following figures.

FIG. 1 illustrates a block diagram of a clock generation circuit with time delay adjustment, according to several embodiments of the invention.

FIG. 2 shows a timing diagram illustrating the operation of a clock generation system with sample clock and delay control signal, according to an embodiment of the invention.

FIG. 3 shows a timing diagram illustrating the operation of redundant delay adjustments in a clock generation system and its application in unit delay estimation, according to an embodiment of the invention.

### DETAILED DESCRIPTION

Turning now to the drawings, clock generation circuits with delay adjustment in accordance with embodiments of the invention are disclosed.

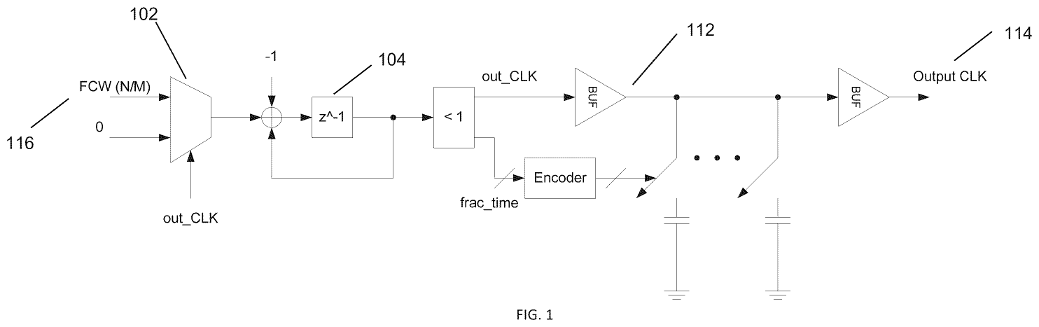

FIG. 1 illustrates a clock generation circuit with time delay adjustment according to various embodiments of the invention. The circuit includes a multiplexer 102 that receives a frequency control word (FCW) input and a feedback signal. The multiplexer 102 connects to an adder/subtractor 104, which processes the digital control signals for timing adjustment. The adder/subtractor 104 feeds into delay elements that work in conjunction with buffer stages 112 to generate precise timing control. The circuit produces an output clock signal 114 that may be derived from a sample clock signal 116 through the various processing stages.

The buffer stages 112 may be implemented as a buffer driving a variable switch-capacitor network, where time delay exhibits a linear relationship with total capacitance at the load. This linear relationship enables precise control over timing adjustments by varying the capacitive loading on the buffer output. The switch-capacitor network configuration allows for fine-grained delay adjustments while maintaining signal integrity throughout the buffer chain. In some embodiments of the invention, the buffer stages 112 incorporate multiple switching elements that can be selectively activated to achieve different capacitive loads and corresponding delay values.

As shown in FIG. 1, the circuit may operate according to specific performance targets that demonstrate the precision achievable with this architecture. In one example implementation according to an embodiment of the invention, the target output clock jitter may reach −154 dBc/Hz at 2 GHz operation with 5 GHz sample clock, with integrated jitter specifications of −61 dBc or 71 fs in the Nyquist bandwidth. The jitter contribution from delay step size may be calculated as step size divided by \sqrt{12}, where the step size measures 246 fs. To cover the period of a 5 GHz sample clock (200 ps), the minimum number of delay steps is 813. Variable time delay implementation needs to be linear with the control signal to provide predictable and stable delay characteristics. One implementation of this time delay is 813 unit-delays controlled by thermometer codes. This implementation is very expensive and not scalable. Alternatively, a zero-DNL DAC controlled time delay can achieve perfect linearity with the delay control signal using redundant delay mappings. The total time delay range with redundant delay mappings needs to cover 2 times of the sample clock period, and with a sample clock signal 116 operating at 5 GHz (corresponding to a 400 ps period), the minimum number of delay steps reaches 1626, though implementations may use 2048 steps to provide additional margin and flexibility. The 2048 steps can be realized with a 3-segments zero-DNL DAC (4-4-3) which most significant bits (MSB) segment has 4 bits (15 unit-delays), next significant bits (NSB) segment 4 bits (31 unit-delays), and least significant bits (LSB) segment 3 bits (15 unit-delays). Total number of unit delays is 61 and significantly lower than the number of steps. Other implementations with different segment configurations or bits are also possible.

This zero-DNL DAC implementation ensures that differential nonlinearity errors duc to delay mismatch (caused by capacitance mismatches) do not introduce unwanted timing variations that could degrade the spectral purity of the output clock signal 114. The time delay step size directly influences the jitter characteristics of the output clock signal 114, making precise step size control important for achieving low-jitter performance.

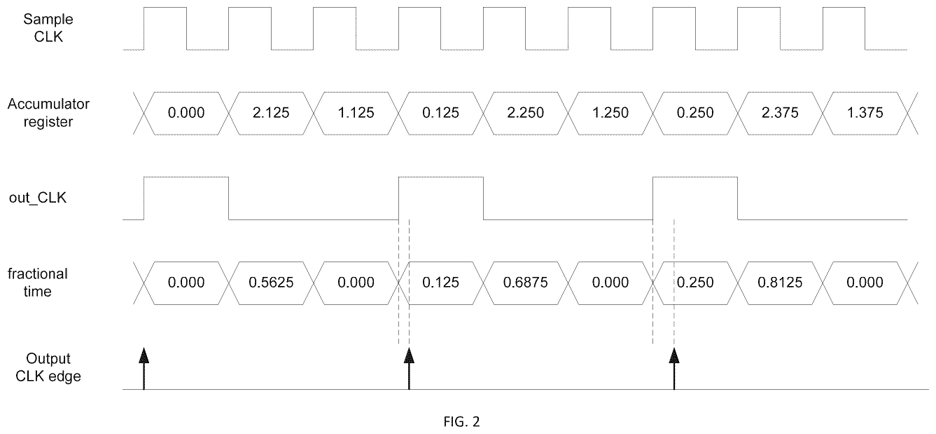

The circuit architecture shown in FIG. 1 provides a fractional clock divider that can generate an M/N clock output where M/N is less than 1, derived from the higher speed sample clock signal 116. A count-down counter, clocked at the sample clock rate, can generate the output clock signal 114 and controls its delay characteristics. The counter mechanism works in conjunction with the multiplexer 102 and adder/subtractor 104 to implement the fractional division algorithm. FIG. 2 provides a timing diagram illustrating the circuit operation using M/N=8/25 as an example, where N/M equals 25/8 or 3.125. During operation, N/M may be added to the counter value when out_CLK equals 1, while the counter value decrements by 1 at every sample clock cycle when out_CLK does not equal 1. The out_CLK signal transitions to 1 when the counter value drops below 1, and frac_time represents the delay between out_CLK and the desired fractional output clock, measured in units of Ts (the sample clock period). The delay adjustment functionality may be implemented through the switch capacitor network configuration integrated within the buffer stages 112 as depicted in FIG. 1.

### Numerically Controlled Oscillator (NCO)

The first half of the circuit that provides out_CLK can be considered a numerically controlled oscillator (NCO). The adder/subtractor 104 implements a frequency control word (FCW) that may be defined as FCW=fₛ/fₒᵤₜ for generating specific output frequencies from the sample clock signal 116. This frequency control word provides the mathematical relationship between the input sample frequency and the desired output frequency, enabling precise fractional clock division. In some embodiments of the invention for example, generating 800 MHz output from a 2500 MHz sample clock signal 116 results in an FCW value of 3.125. The adder/subtractor 104 can process this frequency control word in conjunction with feedback signals from the multiplexer 102 to maintain accurate frequency synthesis. The fractional time output from this processing stage carries units of Tₛ, where Tₛ represents the sample clock period, providing a normalized time reference for subsequent delay adjustment operations.

The NCO may operate according to specific performance targets that demonstrate the precision achievable through this frequency control architecture. The output clock signal 114 may operate at target jitter specifications of −154 dBc/Hz at 2 GHz operation, representing a high level of spectral purity for demanding applications. Integrated jitter specifications may reach −61 dBc or 71 fs within the Nyquist bandwidth, indicating exceptional timing accuracy. These performance parameters result from the careful coordination between the frequency control word processing in the adder/subtractor 104 and the delay adjustment mechanisms implemented throughout the buffer stages 112. The jitter performance depends on multiple factors including the precision of the frequency control word implementation and the linearity of the delay adjustment network.

Referring again to FIG. 1, the buffer stages 112 may implement delay step sizes of 246 fs to achieve the target jitter performance specifications. The system may utilize a minimum of 1626 delay taps to provide adequate resolution for timing adjustments, though some embodiments may employ 2048 taps to offer additional flexibility and margin. These delay step sizes directly influence the quantization noise characteristics of the output clock signal 114, where smaller step sizes generally contribute to lower jitter levels. The relationship between step size and jitter may be calculated as step size divided by \sqrt{v}12, establishing the theoretical noise floor for the timing adjustment system. The selection of 2048 taps provides binary alignment for digital control systems while exceeding the minimum resolution requirements.

The sample clock signal 116 may operate at 5 GHz with a corresponding period of 200 ps, establishing the fundamental timing reference for the entire clock generation system. The total time delay range with zero-DNL DAC configuration covers 2 times the sample clock period, providing 400 ps of total delay adjustment capability. This delay range enables the system to accommodate a full range of fractional timing adjustments while maintaining phase continuity across different operating conditions. The relationship between the sample clock frequency and the delay range determines the overall flexibility of the fractional clock division process. Higher sample clock frequencies generally enable finer timing resolution, while the 2× period delay range ensures adequate coverage for typical fractional division ratios.

### Timing Operation and Signal Relationships

FIG. 2 is a timing diagram showing the operational relationships between multiple synchronized signals (the sample clock, accumulator register, output clock, and fractional time signals) according to various embodiments of the invention. The diagram contains five waveforms illustrating the temporal coordination between different components of the clock generation system.

The sample clock signal at the top of FIG. 2 provides a consistent square wave pattern with uniform high and low periods, serving as the fundamental timing reference. This reference signal establishes the base frequency from which all other timing relationships may be derived. The accumulator register trace below the sample clock displays a sequence of numerical values including 0.000, 2.125, 1.125, 0.125, 2.250, 1.250, 0.250, 2.375, and 1.375, which increment in precise steps according to the frequency control algorithm. M/N=8/25 or N/M=25/8=3.125. N/M is added to the counter value if out_CLK=1. Otherwise, the counter value decrements by 1 at every sample clock. out_CLK=1 if the counter value drops below 1 and this value is frac_time (in unit of Ts, sample clock period). frac_time is the delay between out_CLK and the desired fractional output clock. The delay adjustment can be implemented with the switch capacitor network shown in FIG. 1. These accumulator values represent the digital state maintained by the system to track the fractional timing relationships between input and output clock frequencies.

The output clock signal shown in the middle section of FIG. 2 exhibits wider periods than the sample clock, demonstrating the clock division functionality achieved through the fractional timing control mechanism. This output clock waveform shows how the system generates lower frequency signals from the higher frequency sample clock input. The fractional time signal displays decimal values of 0.000, 0.5625, 0.000, 0.125, 0.6875, 0.000, 0.250, 0.6125, and 0.000, which represent timing intervals between clock edges measured in units of the sample clock period. These fractional time values provide delay adjustment information that controls when output clock transitions occur relative to the sample clock reference.

At the bottom of FIG. 2, the output clock edge signal marks transition points with upward-pointing arrows that align with particular events in the other signals. These arrows indicate the moments when output clock transitions occur based on the accumulator and fractional time calculations performed by the digital control circuitry. The arrows occur at regular intervals that correspond to the output clock transitions.

The accumulator register maintains state information that tracks the fractional portion of each clock cycle, while the fractional time signal provides the specific delay values needed to position output clock edges at the correct temporal locations. The timing relationships demonstrated in FIG. 2 show how the system achieves fractional clock division through coordinated digital processing and analog delay adjustment mechanisms. The consistent patterns in the waveforms reveal the deterministic nature of the timing control algorithm, where each output clock edge may be precisely positioned based on the accumulated fractional timing information maintained in the digital control registers.

### Delay Adjustment

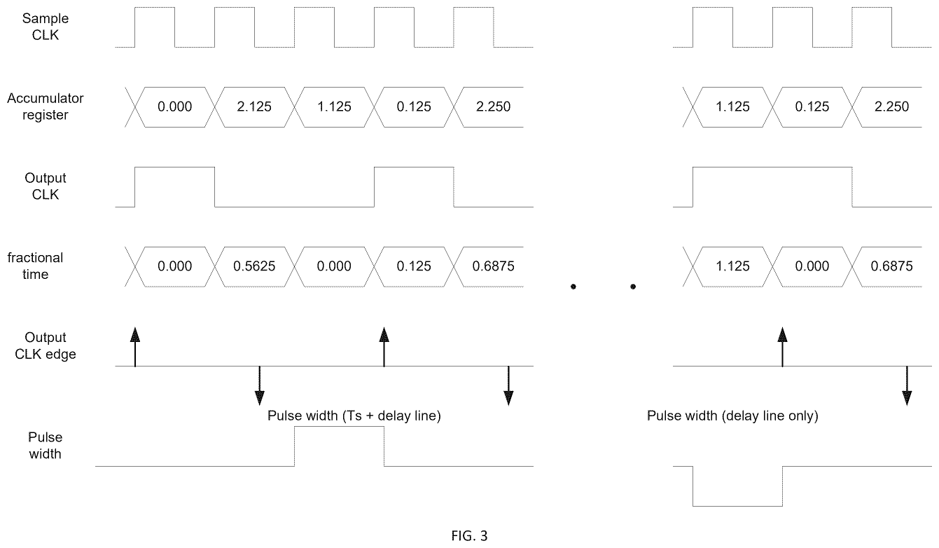

FIG. 3 illustrates a timing diagram showing delay adjustment operation with probabilistic assignment methodology according to various embodiments of the invention. The diagram demonstrates how the system can implement redundant delay mapping techniques to achieve improved timing accuracy while mitigating spurious generation due to any delay errors through stochastic signal processing.

The probabilistic delay assignment methodology shown in FIG. 3 utilizes two probability calculations to control delay setting selection. The multiplexer 102 may implement probabilistic assignment of delay settings using probabilities p1=m1/L and p2=(L−m1)/L to eliminate spurious signals that could otherwise degrade spectral purity. These probability assignments ensure that delay selection follows a stochastic process rather than a deterministic pattern, converting periodic timing errors into random noise components. The probability values depend on the fractional portion m1 of the desired delay and the ratio L representing the relationship between the sample clock period and unit delay. When the system selects between different delay implementations using these calculated probabilities, the ensemble average of the resulting delays approaches the target delay value while distributing any delay errors across a white noise spectrum.

The redundant delay mapping technique provides the mechanism for eliminating spurious signals due to delay errors at the buffer stage. The mathematical relationship E{t}=t+LΔ shows how the ensemble average delay equals the target delay plus a constant offset proportional to the scaling error, while the variance var{t}=Δ2m₁(L−m₁) represents the noise power added to the system. This noise power reaches its maximum when m₁=L/2 and approaches zero when m₁ approaches either 0 or L, indicating that the noise contribution varies with the fractional delay value but remains bounded and predictable.

The buffer stages 112 may implement redundant delay mapping where delays between Tₛ and 2Tₛ have two possible settings: delay line only, or 1Tₛ delay plus delay line. This redundant mapping provides the foundation for the probabilistic assignment methodology by offering multiple paths to achieve the same target delay value. As shown in FIG. 3, the pulse width measurements demonstrate how these two delay implementation methods can produce equivalent timing results when the scaling factors are accurate. The delay line only implementation utilizes the switch-capacitor network to generate the full delay value directly, while the 1Tₛ delay plus delay line approach combines a fixed sample clock period delay with a variable delay line component. The availability of these two implementation methods enables the system to detect and compensate for scaling errors by comparing the actual delays produced by each approach.

Scaling Factor Tₛ/t_{d} Estimation

In many embodiments of the invention, the system includes a Tₛ/t_{d} ratio estimation circuit that may continuously operate in the background to track scaling factors and minimize scaling errors. This ratio estimation circuit can monitor the relationship between the sample clock period Tₛ and the unit delay t_{d} of the delay adjustment network, providing real-time calibration of the timing system. The estimation circuit compares two different delay implementation methods for delays between Tₛ and 2Tₛ: delay line only, and 1Tₛ delay plus delay line. When these two methods produce identical delays, the Tₛ/t_{d} ratio estimation may be considered accurate. Any discrepancy between these two delay methods indicates a scaling error that the estimation circuit can detect and correct. The continuous background operation of this estimation circuit ensures that process, voltage, and temperature variations do not degrade the timing accuracy of the clock generation system over time.

Referring again to FIG. 3, the timing diagram shows how the system can compare two delay methods for Tₛ/t_{d} estimation. The pulse width signal at the bottom of the diagram illustrates the two delay implementation methods operating with different timing characteristics due to scaling errors in the unit delay elements. When the two delay methods produce identical results, two pulses have the same width, and the DC value of the pulse width signal is zero. However, when scaling errors cause the two methods to produce different delays, there would be difference between two pulses, and the DC value of the pulse width signal is not zero. The pulse signal can be used to drive an estimation loop. The system may continuously monitor the difference between the two delay implementation methods for delays in the Tₛ to 2Tₛ range, using this information to update the Tₛ/t_{d} ratio estimation.

Although the description above contains many specificities, these should not be construed as limiting the scope of the invention but as merely providing illustrations of some of the presently preferred embodiments of the invention. Various other embodiments are possible within its scope. Accordingly, the scope of the invention should be determined not by the embodiments illustrated, but by the appended claims and their equivalents.

1. A clock generation circuit, comprising:
a numerically controlled oscillator (NCO) configured to receive a frequency control word and generate a fractional time signal;
a variable delay circuit comprising a buffer driving a variable switch-capacitor network, the variable delay circuit configured to receive the fractional time signal and generate a delayed clock signal with a time delay that is linear with total capacitance at a load using probabilistic delay assignment; and
a probabilistic delay assignment circuit configured to select between a first delay setting comprising delay line only and a second delay setting comprising a sample clock period delay plus delay line, wherein the probabilistic delay assignment circuit assigns probabilities p1=m1/L and p2=(L−m1)/L for selecting the first and second delay settings respectively, where m1 represents a fractional portion of a desired delay and L represents a ratio between a sample clock period and a unit delay.

2. The clock generation circuit of claim 1, wherein the numerically controlled oscillator comprises an adder/subtractor configured to process the frequency control word and a multiplexer configured to receive feedback signals.

3. The clock generation circuit of claim 1, wherein the variable switch-capacitor network comprises a plurality of switching elements that are selectively activated to achieve different capacitive loads and corresponding delay values.

4. The clock generation circuit of claim 3, wherein the variable delay circuit incorporates a zero-DNL DAC configuration for linear skew control to minimize jitter in the delayed clock signal.

5. The clock generation circuit of claim 1, further comprising a ratio estimation circuit configured to continuously monitor a relationship between a sample clock period Tₛ and a unit delay td of the variable delay circuit.

6. The clock generation circuit of claim 5, wherein the ratio estimation circuit compares the first delay setting and the second delay setting for delays between Tₛ and 2Tₛ to detect scaling errors.

7. The clock generation circuit of claim 6, wherein the probabilistic delay assignment circuit converts delay errors to zero-mean additive white noise using stochastic signal processing to eliminate periodic spurious signals.

8. A method for generating a clock signal with delay adjustment, comprising:
receiving a frequency control word at a numerically controlled oscillator;
generating a fractional time signal based on the frequency control word;
applying the fractional time signal to a variable delay circuit comprising a buffer driving a variable switch-capacitor network to produce a time delay that is linear with total capacitance at a load using probabilistic delay assignment; and
probabilistically selecting between a first delay implementation using delay line only and a second delay implementation using a sample clock period delay plus delay line, wherein the probabilistic selection uses probabilities p1=m1/L and p2=(L−m1)/L, where m1 represents a fractional portion of a desired delay and L represents a ratio between a sample clock period and a unit delay.

9. The method of claim 8, wherein generating the fractional time signal comprises processing the frequency control word through an adder/subtractor and maintaining an accumulator register that tracks fractional timing relationships.

10. The method of claim 9, wherein the accumulator register increments by a ratio N/M when an output clock signal equals 1 and decrements by 1 at every sample clock cycle otherwise, where N/M represents the frequency control word.

11. The method of claim 8, wherein the variable switch-capacitor network comprises a plurality of switching elements that are selectively activated to achieve different capacitive loads corresponding to different delay values.

12. The method of claim 11, wherein applying the fractional time signal comprises utilizing a zero-DNL DAC configuration for linear skew control to minimize jitter in a resulting delayed clock signal.

13. The method of claim 8, further comprising continuously monitoring a relationship between a sample clock period Tₛ and a unit delay td using a ratio estimation circuit operating in background.

14. The method of claim 13, wherein the ratio estimation circuit compares actual delays produced by the first delay implementation and the second delay implementation to detect scaling errors and update the ratio L accordingly.

15. A fractional clock divider circuit, comprising:
an accumulator configured to maintain a count value based on a frequency control word;
a comparator configured to generate an output clock signal when the count value drops below a threshold;
a delay adjustment circuit comprising a switch-capacitor network configured to provide variable time delays that are linear with capacitance; and
a ratio estimation circuit configured to estimate a ratio between a sample clock period and a unit delay by comparing two delay implementations for delays between the sample clock period and twice the sample clock period, wherein a first delay implementation uses delay line only and a second delay implementation uses the sample clock period delay plus delay line.

16. The fractional clock divider circuit of claim 15, wherein the accumulator is configured to increment by a ratio N/M when the output clock signal equals 1 and decrement by 1 at every sample clock cycle otherwise, where N/M represents the frequency control word.

17. The fractional clock divider circuit of claim 15, wherein the switch-capacitor network comprises a plurality of switching elements that are selectively activated to achieve different capacitive loads corresponding to different delay values.

18. The fractional clock divider circuit of claim 17, wherein the delay adjustment circuit incorporates a zero-DNL DAC configuration for linear skew control to minimize jitter in a delayed output signal.

19. The fractional clock divider circuit of claim 15, wherein the ratio estimation circuit operates continuously in background and updates the ratio estimation when a difference is detected between actual delays produced by the first delay implementation and the second delay implementation.

20. The fractional clock divider circuit of claim 19, wherein the ratio estimation circuit generates a pulse width signal having a DC value of zero when the ratio estimation is accurate.
